(19) United States
(12) Patent Application Publication
(10) Pub. No.: US 2005/0148174 A1
(43) Pub. Date: Jul. 7, 2005

(54) Contact-connection of nanotubes

(75) Inventors: Eugen Unger, Augsburg (DE); Georg S. Dusberg, Munich (DE); Franz Kreupl, Munich (DE); Andrew Graham, Munich (DE); Maik Liebau, Munich (DE)

Correspondence Address: DARBY & DARBY P.C., P. O. BOX 5257, NEW YORK, NY, 10150-5257, US

(73) Assignee: Infineon Technologies AG, Munich (DE)

(21) Appl. No.: 10/980,983

(22) Filed: Nov. 3, 2004

Related U.S. Application Data
(63) Continuation of application No. PCT/EP03/03341, filed on Mar. 31, 2003.

(30) Foreign Application Priority Data
May 6, 2002 (DE) 102 20 194.3

(51) Int. Cl. H01L 29/417; H01L 29/74; H01L 31/111; H01J 1/02; H01L 21/44

(52) U.S. Cl. 438/678

(57) ABSTRACT

Process for contact-connection of carbon nanotubes as part of their integration in an electric circuit, wherein the nanotubes, after they have been applied to metallic interconnects of the electric circuit, are connected to the interconnects at contact locations by electroless metallization.

### CROSS-REFERENCE TO RELATED APPLICATION

This application is a continuation of International Patent Application Serial No. PCT/EP2003/003341, filed Mar. 31, 2003, which published in German on Nov. 13, 2003 as WO 2003/094226, and is incorporated herein by reference in its entirety.

### FIELD OF THE INVENTION

The present invention relates to a process for the contact-connection of nanotubes, in particular carbon nanotubes, as part of their integration in an electric circuit, wherein the nanotubes, after they have been applied to the metallic interconnects of the electric circuit, are connected to the interconnects at the contact locations by electroless metallization.

### BACKGROUND OF THE INVENTION

On account of the fact that nanotubes, in particular carbon nanotubes, are suitable for use as metallic conductors and as semiconductors, within the context of nanocircuitry it is desirable for nanotubes of this type to be fixed to electric circuits or electronic components. The use of nanotubes as component parts, e.g. in electric circuits, requires them to be contact-connected to metallic conductors. Nanotubes of this type are usually available as dispersions, as a sheet or bucky paper or as a powder. If dispersions of this type are applied to electric circuits, random distributions of bundles of nanotubes and isolated nanotubes are usually obtained and are held on a surface of the electronic component which has been provided with electrical conductors by van der Waals forces.

For nanotubes to be used as conductors or as active component parts, they have to be contact-connected to the interconnects in an electric circuit in such a manner that the contact locations present the lowest possible resistance to the current. Furthermore, it is necessary for the nanotubes to be sufficiently mechanically anchored or fixed at the contact locations. However, without any treatment of the nanotube/interconnect contact locations, i.e. if the nanotubes are held or deposited on the interconnect only by means of van der Waals forces, contact resistances of several hundred kiloohms (kΩ) or even up to megaohms (MΩ) are observed, making it much more difficult to use nanotubes of this type in electric circuits.

Hitherto, in some cases it was only possible to achieve low-resistance contact between nanotubes and interconnects at considerable cost. For example, Bachtold et al., Applied Physics Letters, Vol. 73, No. 2, 1998, pages 274 to 276, describes the “soldering” of carbon nanotubes to gold contacts by means of an electron beam, with the result that carbon from the residual gas is deposited at the contact location in the manner of a “focal spot”. Furthermore, it is possible to deposit metal at the contact locations using a focused ion beam installation. For example, Wei et al., Applied Physics Letters, Vol. 74, No. 21, 1999, pages 3149 to 3151, describes the deposition of tungsten at the contact locations by means of a focused ion beam installation of this type using W(CO)₆ as tungsten source. Furthermore, in a photolithographic step a resist layer can be patterned over the circuit in such a manner that openings, through which metal, for example titanium, is applied in vacuo, are formed above the contact locations. After a lift-off step, the metal remains only at the contact locations; cf. Zhang et al., Chemical Physics Letters, 331 (2000), pages 35 to 41. These processes are generally also followed by a heat treatment to improve the contact locations. However, the above processes are extremely complex. Furthermore, these processes cannot be used or can scarcely be used to fix entire bundles or arrays of nanotubes after they have grown.

### SUMMARY OF THE INVENTION

Therefore, the present invention is based on an object of providing a process for the contact-connection of nanotubes, in particular carbon nanotubes, as part of their integration in an electric circuit, which is intended on the one hand to provide the contact between nanotube and interconnect with the lowest possible resistance and on the other hand at the same time to ensure a mechanically fixed contact between nanotube and interconnect. It should be possible for a process of this type to be carried out in a simple and as far as possible highly parallel way.

This object is achieved by the embodiments which are described in the claims.

In particular, an embodiment of the invention provides a process for the contact-connection of nanotubes as part of their integration in an electric circuit, comprising the steps of:
(a) applying a predetermined interconnect arrangement, comprising at least two interconnects, to a substrate,
(b) applying at least one nanotube to the substrate which has been patterned in this manner in step (a), and
(c) subjecting the substrate obtained in step (b) to an electroless metallization in a bath process using an aqueous electrolyte containing metal cations, such that metal is deposited on the interconnect arrangement so as to at least partially enclose the at least one nanotube at its locations of contact with the interconnects.

According to the process of an embodiment of the present invention, metal is deposited electrolessly, in a simple bath process, on suitably prepared contact surfaces or interconnects of a provided microcircuit for the purpose of contact-connection of nanotubes. The process according to an embodiment of the invention particularly advantageously does not need complex vacuum installations for the contact-connection of the nanotubes.

### BRIEF DESCRIPTION OF THE DRAWINGS

FIGS. 1 and 2 show scanning electron microscope images of an excerpt from a microcircuit in which carbon nanotubes have been contact-connected by means of a process according to an embodiment of the invention.

### DETAILED DESCRIPTION OF AN EMBODIMENT OF THE INVENTION

A process according to an embodiment of the invention particularly advantageously allows both individual nanotubes and arrays of nanotubes to be contact-connected in a mechanically fixed form on predetermined interconnect arrangements in a highly parallel process. The contact locations produced have a considerably lower resistance than if the nanotubes are held or deposited on the interconnects only by means of van der Waals forces. The contact locations produced as part of a process according to an embodiment of the invention usually have contact resistances of 10 kΩ or below.

In step (a) of a process according to an embodiment of the invention, first of all a predetermined interconnect arrangement comprising at least two interconnects is applied to a substrate. This can usually be effected by means of a conventional pattern-plating process. In this process, a photoresist layer with a predetermined depth structure is applied to the substrate, i.e. the substrate is covered by a photoresist with a suitable preliminary pattern or a predetermined pattern comprising recesses (depth structure). Substrates which can preferably be used include precious metals, oxidic glasses, monocrystalline or multicrystalline substrates, semiconductors, metals with or without passivated surface, insulators or, in general, substrates with a high resistance to the subsequent etching procedures. These include in particular Pt, Au, GaAs, In_{y}GaAs, AlₓGaAs, Si, SiO₂, Ge, SiₓN_{y}, SiₓGaAs, InP, InPSi, GaInAsP, glass, graphite, diamond, mica, SrTiO₃ and the doped modifications thereof. The substrates that can be used may be both planar, flat substrates and substrates with planar, (convexly or concavely) curved surfaces. The commercially available photoresists which are known from the prior art can be used as the photoresists. A smooth substrate, such as in particular silicon with an SiO₂ layer thereon, can be coated with a photoresist, by way of example by spin coating. The thickness of the film may be between 10 nm and several μm. Then, the photoresist is exposed in the usual way through a mask using visible light, UV radiation, X-radiation or electron radiation in the desired, predetermined patterns. The photoresist is then developed, i.e. either the exposed part is dissolved out of the film (positive photoresist) or the unexposed photoresist is dissolved out of the film (negative photoresist). The patterns and structures which have been introduced constitute depressions in the photoresist with a depth corresponding to the photoresist layer thickness. The structures may be periodic or aperiodic. The depressions may, for example, have a length and a width of between 15 nm and several μm and a depth of between 5 nm and several micrometers. It is in particular possible to form predetermined structures which are larger than 40 nm. A predetermined structure may also be formed, for example, just by a wall of the photoresist film, i.e. in the sense of a step. Then, metal is applied to the substrate which has been pre-patterned in this manner, for example by means of sputtering techniques, vapor deposition or spin-on techniques. There is no specific restriction on the metal to be used for this purpose. By way of example, it is possible to apply a layer of gold, in particular in combination with a layer of iron. In this context, it is of no importance whether the iron is arranged below, above or even in sandwich form around the layer of gold, which is usually very thin, (e.g. 5 to 50 nm thick). Alternatively, by way of example, it is also possible to provide an Au/Ti layer arrangement if iron is located above the layer of gold. Final removal of the photoresist mask by means of a lift-off technique e.g. etching, leads to the desired interconnect arrangement on the substrate.

In step (b) of a process according to an embodiment of the invention, at least one nanotube is applied to or deposited on the substrate which has been patterned in step (a), i.e. the predetermined interconnect arrangement or the intended microcircuit.

The nanotubes used in step (b) may be either single-walled or multi-walled in form. In the case of multi-walled nanotubes, at least one inner nanotube is coaxially surrounded by an outer nanotube. It is preferable for the nanotubes which can be used in the process according to an embodiment of the invention to be carbon nanotubes, carbon nanotubes doped with boron nitride or oxidized carbon nanotubes. Carbon nanotubes are particularly preferred.

In step (b), the nanotubes are applied to the substrate produced in step (a) preferably by means of an airbrush process. For this purpose, the nanotubes are usually dispersed in a polar organic solvent. Suitable examples of such solvents may include dimethylformamide, acetonitrile, methylene chloride, chloroform, methanol and ethanol. Dimethylformamide is particularly suitable. Alternatively, the nanotubes may also be dispersed in water. The concentration of the nanotubes in dispersions of this type is usually 1 to 30 mg/l. In DMF, the concentration is, for example, ≦25 mg/l. After application, the nanotubes which have been deposited on the substrate can if appropriate be selected and/or positioned using high-resolution methods, such as atomic force microscopy, so that at least one nanotube is in contact with two interconnects. By way of example, at least one nanotube can bridge two interconnects running substantially parallel to one another.

Then, in step (c) of a process according to an embodiment of the invention, at least one metal is deposited by electroless or chemical metallization (electroless plating) from an aqueous electrolyte on the interconnect(s) and therefore at the same time also the nanotube/interconnect contact locations, so as to at least partially enclose the nanotubes, with the result that they are fixedly contact-connected to the interconnect. The contact-connection is achieved selectively and can be implemented at locations which cannot be reached by conventional PVD metal deposition. Moreover, the metallization takes place very quickly. In general, the contact locations and interconnects are sufficiently coated in less than one minute. The fixed enclosing of the nanotube at the contact locations within the interconnect arrangement ensures the mechanical stability thereof in the finished circuit or electronic component.

The electrolyte compositions which can be used in step (c) of the process according to an embodiment of the invention are fundamentally known from the technology of surface treatment, corrosion treatment or printed circuit board production. By way of example, in the context of the process according to an embodiment of the invention, it is possible for metals such as in particular nickel, tin, copper, cobalt, platinum, palladium and gold and alloys thereof preferably nickel or copper to be deposited electrolessly from aqueous solution, i.e. from the metal salts thereof, on suitable surfaces. Electrolyte compositions of this type are known in the prior art and are used, for example, for corrosion prevention purposes or to produce electrical conductivity on extensively patterned, uneven surfaces for which vacuum metallization is not suitable for process or cost reasons.

If there is a chemical potential drop between the metal salt or the metal cations of the aqueous electrolyte containing metal cations and the metal or alloy of the applied interconnect, the more base metal of the interconnect arrangement is oxidized, whereas the metal cations of the electrolyte are reduced and precipitate on the interconnect arrangement. The structure of the deposits formed is generally fine-grained. The deposits generally also contain certain incorporated electrolyte constituents or the intermediate products thereof.

The precipitates formed also have a catalytic effect for the further metallization. This is because if there is no longer a sufficient chemical potential drop, the further deposition within the context of the process according to an embodiment of the invention is usually achieved by a reducing compound, such as for example formaldehyde for Cu²⁺ or hypophosphite or borohydride for Ni²⁺ or Co²⁺, being added to the electrolyte composition for the electroless plating.

In order, for example, as part of the present invention, to nickel-plate the corresponding interconnect arrangement with one or more nanotubes deposited thereon, it is possible, for example, as is known in the prior art, to reduce nickel(II) chloride using hypophosphite. Nickel is then deposited on the interconnect arrangement so as to cover the nanotube/interconnect contact location(s). The pH is usually set to 8 to 9. Alternatively, however, metallizations in an acidic medium at a pH in the range from 4 to 6 are also possible. If the pH is too alkaline, nickel hydroxide or basic salts would be precipitated out. A reaction of this nature can be avoided by the addition of complex-forming agents, such as for example citrate (or seignette salt in the case of copper), resulting in the formation of a nickel(II) complex, so that the concentration of nickel(II) in the electrolyte solution is reduced. The baths which can be used in the process according to an embodiment of the invention may generally contain the bath additives which are known in the prior art, such as stabilizers, activators or depolarizers, conductive salts, inhibitors, wetting agents, brighteners, etc.

The deposits or layers which have been formed in accordance with an embodiment of the invention may if appropriate also be thickened by electroplating.

The deposition rate in step (c) of the process according to an embodiment of the invention is usually 130 to 300 nm/min. The coatings deposited in this step may, for example, have a thickness in the range from 50 nm to a few micrometers.

After the electroless metallization, the substrate which has been treated in this manner is rinsed and dried in the usual way. A conditioning step can then also be carried out in vacuo or under an inert gas atmosphere using temperatures of up to 1000° C. depending on the metallic base, for example temperatures in the range from 300 to 500° C. for nickel on gold, in order to effect substantially homogenous fusion of the deposited metal layer. Prior to a conditioning step of this type, the deposited metal layer, which substantially completely covers the interconnects and the nanotubes with metal at their contact locations, still have a more or less fine grain size.

A further embodiment of the present invention is an electronic component or an electrical circuit having a substrate with at least two interconnects and at least one nanotube on the substrate and on at least two of the interconnects, the nanotube being in electrical contact with the at least two interconnects, the nanotube being at least partially enclosed by a metal on the at least two interconnects. In particular, an electronic component of this type comprises a substrate having an interconnect arrangement comprising at least two interconnects, at least one nanotube being in contact with the at least two interconnects, and the nanotubes/interconnect contact locations having a contact resistance of ≦10 kΩ. A component of this type is obtainable by the process according to an embodiment of the invention.

The present invention is explained in more detail by the following example.

### EXAMPLE

First of all, a thin (approximately 10-20 nm) iron and gold layer is applied to a silicon substrate on which there is arranged an SiO₂ layer amounting to a few hundred nanometers, by means of a sputtering technique using a conventional photoresist mask which has already been pre-patterned with the predetermined contact surfaces or interconnects. Alternatively, a titanium-gold layer was also applied, and a 10 nm thick iron layer was then sputtered onto this layer. After the lift-off step, the correspondingly desired, predetermined interconnect pattern was obtained on the SiO₂ surface.

Then, a dispersion of carbon nanotubes in dimethylformamide/isopropanol was applied by spraying to the substrate which had been provided with the predetermined interconnect pattern (airbrush process).

Then, the substrate was immersed for 15 seconds in an ammoniacal metallization solution at a temperature of 85° C. which, with a pH of approximately 9, contained approximately 21 g of nickel chloride, 24 g of sodium phosphinate, 40 g of trisodium citrate and 50 g of ammonium chloride per liter. This metallization solution had a pH of approximately 9. To obtain a reproducible reactivity of the metallization solution, first of all, prior to immersion of the substrate, an untreated silicon substrate was immersed in this metallization solution until it was possible to detect significant levels of gas evolution and nickel plating. After the electroless metallization, the substrate was rinsed with water and isopropanol and dried.

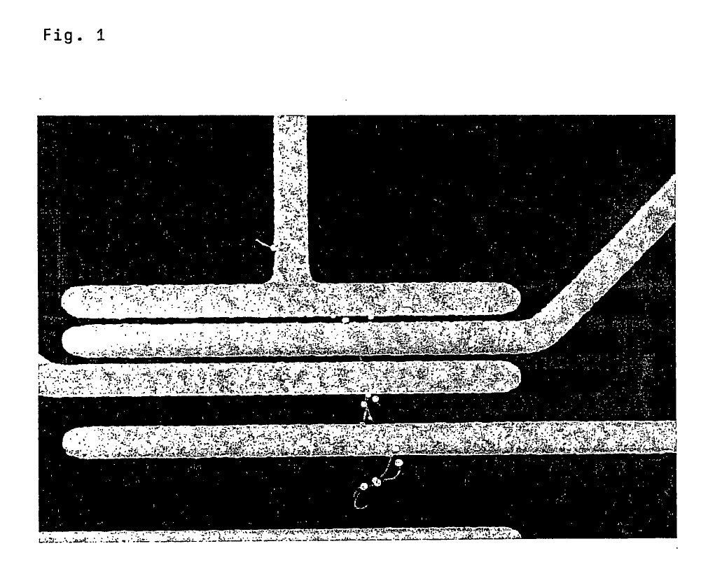

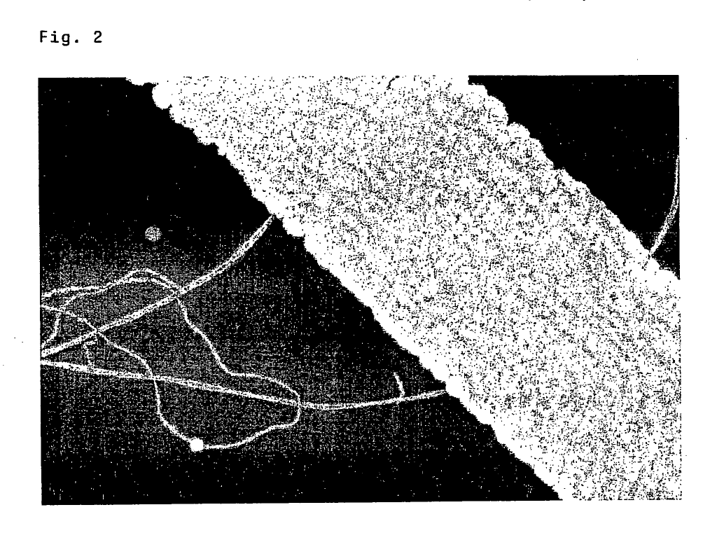

The specimens produced were examined by scanning electron microscopy (SEM). FIGS. 1 and 2 show SEM images of an excerpt from a microcircuit in which carbon nanotubes have been contact-connected in accordance with the present invention. FIG. 1 shows that the interconnects and the nanotubes are completely covered with nickel at the contact locations. The nanotubes are “buried” below the deposited nickel layer on the surfaces of the interconnects. The nanotube path can still be seen clearly in FIG. 1. FIG. 2 shows an enlarged excerpt from FIG. 1. The interconnects arranged on the substrate have not widened to such an extent that they touch one another. The SEM images were taken before a final conditioning step. In the subsequent conditioning step, significantly more homogeneous fusion of the deposited nickel layer is effected. Moreover, the contact resistances are reduced by a factor of 2 to 3 compared to the values measured in the unconditioned state.

Before a conditioning step of this type, the deposited nickel layer, which completely covers the interconnects and the nanotubes with nickel at their contact locations, usually still has a more or less fine grain size.

1. A process for contact-connection of nanotubes as part of their integration in an electric circuit, comprising the steps of:
(a) applying a predetermined interconnect arrangement, comprising at least two interconnects, to a substrate;
(b) applying at least one nanotube to the substrate, which has been patterned in step (a); and
(c) subjecting the substrate obtained in step (b) to an electroless metallization in a bath process using an aqueous electrolyte containing metal cations, such that metal is deposited on the interconnect arrangement so as to at least partially enclose the at least one nanotube at its locations of contact with the interconnects.

2. The process as claimed in claim 1, wherein the at least one nanotube is selected from the group consisting of carbon nanotubes, carbon nanotubes doped with boron nitride, and oxidized carbon nanotubes.

3. The process as claimed in claim 1, wherein in step (a) the application of the predetermined interconnect arrangement is carried out using a pattern-plating process.

4. The process as claimed in claim 1, wherein in step (b) the nanotubes are applied using an airbrush process.

5. The process as claimed in claim 1, wherein, after being applied in step (b), the at least one nanotube which has been applied to the substrate is selected and/or positioned by atomic force microscopy such that at least one nanotube is in contact with two interconnects.

6. The process as claimed in claim 1, wherein in the bath process in accordance with step (c) at least one metal selected from the group consisting of nickel, tin, copper, cobalt, platinum, palladium, and gold, and alloys thereof, preferably nickel or copper, is/are deposited electrolessly from aqueous solution.

7. The process as claimed in claim 6, wherein the metal is nickel or copper.

8. The process as claimed in claim 1, further comprising a conditioning step, which is carried out after step (c).

9. The process as claimed in claim 1, wherein the deposition rate in step (c) is 130 to 300 nm/min.

10. The process as claimed in claim 1, wherein the nanotube/interconnect contact locations have a contact resistance of ≦10 kΩ.

11. The process as claimed in claim 1, wherein the substrate is selected from the group consisting of Pt, Au, GaAs, In_{y}GaAs, AlₓGaAs, Si, SiO₂, Ge, SiₓN_{y}, SiₓGaAs, InP, InPSi, GaInAsP, glass, graphite, diamond, mica, SrTiO₃, and the doped modifications thereof.

12. An electronic component having a substrate with at least two interconnects and at least one nanotube on the substrate and on at least two of the interconnects, the at least one nanotube being in electrical contact with the at least two interconnects and being at least partially enclosed by a metal on the at least two interconnects.
